(19) United States
(12) Patent Application Publication
(10) Pub. No.: US 2013/0285039 A1
(43) Pub. Date: Oct. 31, 2013

(54) Organic Light-Emitting Device and Light Source Device Using the Same

(71) Applicants: Shingo Ishihara, Mito (JP); Hiroshi Sasaki, Mito (JP); Akitoyo Konno, Hitachi (JP); Shunichiro Nobuki, Mito (JP); Hiroki Kaneko, Hitachinaka (JP)

(72) Inventors: Shingo Ishihara, Mito (JP); Hiroshi Sasaki, Mito (JP); Akitoyo Konno, Hitachi (JP); Shunichiro Nobuki, Mito (JP); Hiroki Kaneko, Hitachinaka (JP)

(73) Assignee: Hitachi ,Ltd., Chiyoda-ku ,Tokyo (JP)

(21) Appl. No.: 13/980,265

(22) PCT Filed: Jan. 23, 2012
(86) PCT No.: PCT/JP2012/051367

§ 371 Date: Jul. 17, 2013

(30) Foreign Application Priority Data
Jan. 24, 2011 (JP) 2011-011502

(51) Int. Cl. H01L 51/50

(52) U.S. Cl. CPC H01L 51/504
USPC 257/40

(57) ABSTRACT

In order to improve an external quantum efficiency of an organic light-emitting element, a first light extraction layer is formed over the surface of a second substrate on the side where the second substrate is present, a second light extraction layer is formed over the surface of the second substrate on the other side, the first and second light extraction layers contain fine particles and a binder, the average particle diameter of the fine particles contained in the first and second light extraction layers are 0.05 μm or more and 2 μm or less and 1 μm or more and 10 μm or less, respectively, and an optical length L₁ between the emission point of the light emitting layer and a first electrode satisfies (2m−155/180)λ₀/4/cos 35°≦L₁≦(2m−155/180)λ₀/4/cos 50°, where λ₀ is a center emission wavelength of the light emitting layer and m is an integer of 1 or more.

### TECHNICAL FIELD

The present invention concerns an organic electroluminescent device and a light source device using the same.

### BACKGROUND ART

A patent literature 1 discloses the following technique as an existent example. It intends to provide an organic electroluminescent element (organic EL element) with a simple and convenient manufacturing process and having high external quantum efficiency, in a configuration of substrate/transparent electrode/organic EL layer/reflection electrode in which a high refractive index layer having surface unevenness on the side of the transparent electrode is provided to the substrate.

### CITATION LIST

### Patent Literature

[Patent Literature 1] Japanese Unexamined Patent Application Publication No. 2008-66027

### SUMMARY OF THE INVENTION

### Technical Problem

In the organic light-emitting element having a light extraction layer, improvement of the external quantum efficiency is difficult in the light extraction layer of the prior art. The present invention intends to improve the external quantum efficiency in an organic light-emitting device using an organic light-emitting element and a light source using the same.

### Solution to Problem

The feature of the present invention for solving the subject is as described below.

(1) An organic light-emitting device having an organic light-emitting element substrate and a light extraction substrate in which the organic light-emitting element substrate has a first substrate, a first electrode, an organic layer, and a second electrode, the first electrode is formed over the first substrate, the organic layer is formed over the first electrode, the second electrode is formed over the organic layer, the light extraction substrate is formed over the second electrode, the organic layer contains a light emitting layer, the light extraction substrate has a first light extraction layer, a second substrate, and a second light extraction layer, the first light extraction layer is formed over the surface of the second substrate on the side where the second electrode is present, the second light extraction layer is formed over the surface of the second substrate on the side where the second electrode is not present, the first light extraction layer contains fine particles and a binder, the second light extraction layer contains fine particles and a binder, the average particle diameter of the fine particles contained in the first light extraction layer is 0.05 μm or more and 2 μm or less, the average particle diameter of the fine particles contained in the second light extraction layer is 1 μm or more and 10 μm or less, and an optical length L₁ between an emission point of the light emitting layer and the first electrode satisfies the (formula 1).

(2m−155/180)λ₀/4/cos 35°≦L₁≦(2m−155/180)λ₀/4/cos 50° (Formula 1)

(λ₀ is a center emission wavelength and m is an integer of 1 or greater)
(2) The organic light-emitting device according to (1) described above, in which the average particle diameter of the fine particles contained in the first light extraction layer is 0.1 μm or more and 1 μm or less, and the average particle diameter of the fine particles contained in the second light extraction layer is 1 μm or more and 5 μm or less.
(3) The organic light-emitting device according to (1) described above, in which the organic light-emitting element substrate and the light extraction substrate are closely bonded by way of a high refractive index resin layer, the refractive index of the high refractive resin layer is 1.6 or more, and the thickness of the high refractive index layer is 5 μm or more and 200 μm or less.
(4) An organic light-emitting device according to (1) described above in which the light emitting layer is a blue light emitting layer, a light emission unit is formed between the organic layer and the second electrode, the light emission unit contains a red light emitting layer and a green light emitting layer, a charge generation layer is formed between the light emission unit and the organic layer, and an optical length L₂ between the emission point of the red light emitting layer and the first electrode, and an optical length L₃ between the emission point of the green light emitting layer and the first electrode satisfy (formula 2) and (formula 3).

(2m−155/180)λ₁/4/cos 35°≦L₂≦(2m−155/180)λ₁/4/cos 50° (Formula 2)

(λ₁ is a center emission wavelength of the red light emitting layer and m is an integer of 1 or greater)

(2m−155/180)λ₂/4/cos 35°≦L₃≦(2m−155/180)λ₂/4/cos 50° (Formula 3)

(λ₂ is a center emission wavelength of the green light emitting layer and m is an integer of 1 or greater)
(5) An organic light-emitting device according to (1) described above in which a light emitting layer is a red light emitting layer, a first charge generation layer is formed over the organic layer, a green light emitting layer is formed over the first charge generation layer, a second charge generation layer is formed over the green light emitting layer, a blue light emitting layer is formed over the second charge generation layer, the second electrode is formed over the blue light emitting layer, and an optical length L₂ between the emission point of the green light emitting layer and the first electrode, and an optical length L₃ between the emission point of the blue light emitting layer and the first electrode satisfy (formula 4) and (formula 5).

(2m−155/180)λ₁/4/cos 35°≦L₂≦(2m−155/180)λ₁/4/cos 50° (Formula 4)

(λ₁ is a center emission wavelength of the green light emitting layer and m is an integer of 1 or greater)

(2m−155/180)λ₂/4/cos 35°≦L₃≦(2m−155/180)λ₂/4/cos 50° (Formula 5)

(λ₂ is a center emission wavelength of the blue light emitting layer and m is an integer of 1 or greater)
(6) An organic light-emitting device according to (1) described above in which the fine particles contained in the first light extraction layer comprise one or more of titanium oxide, zirconium oxide, and barium titanate.
(7) An organic light-emitting device according to (1) described above in which the fine particles contained in the second light extraction layer comprise one or more of titanium oxide, zirconium oxide, and barium titanate.

### Advantageous Effects of Invention

According to the invention, an external quantum efficiency of the organic light-emitting element and the light source device using the same can be improved. Other subjects, constitutions, and effects than those described above will become apparent by the explanation for the following embodiments.

### BRIEF DESCRIPTION OF DRAWINGS

FIG. 1 is a cross sectional view of an organic light-emitting device according to a first embodiment of the invention.

FIG. 2 is a view for manufacturing a light extraction substrate according to the first embodiment of the invention.

FIG. 3 is a view for manufacturing a light extraction layer according to the first embodiment of the invention.

FIG. 4 is a cross sectional view of an organic light-emitting device according to the first embodiment of the invention.

FIG. 5 is a cross sectional view of an organic light-emitting device according to the first embodiment of the invention.

### DESCRIPTION OF EMBODIMENTS

The embodiments of the invention are to be described with reference to the drawings, etc. The following description shows specific embodiments for the content of the invention but the invention is not restricted to the description for them and various changes and modifications are possible by persons skilled in the art within the range of the technical idea disclosed in the present specification. Further, throughout the drawings for explaining the invention, those having identical functions carry the same reference signs and duplicate description thereof is sometimes omitted.

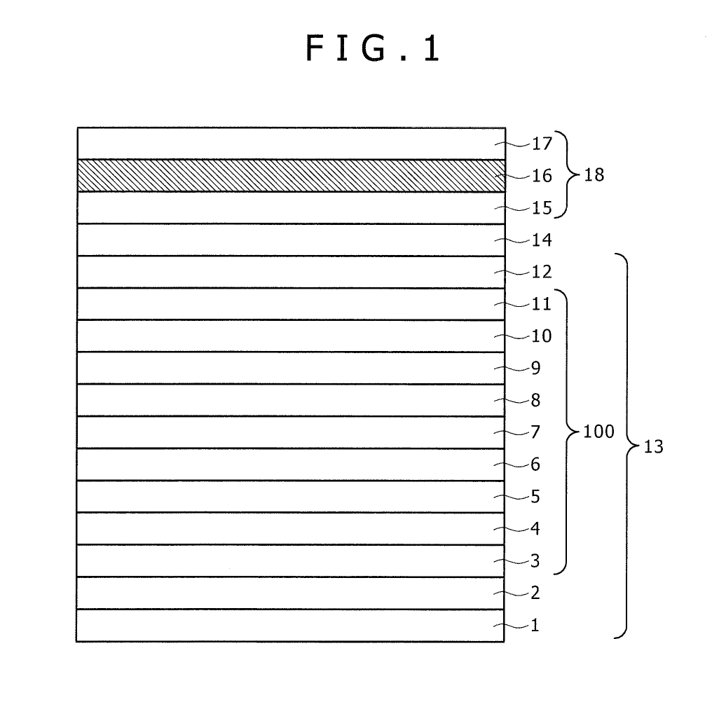

FIG. 1 is a cross sectional view of an organic light-emitting device according to the first embodiment of the invention. The organic light-emitting device has an organic light-emitting element substrate 13 and a light extraction substrate 18. The organic light-emitting element substrate 13 has a first substrate 1, a lower electrode 2, an organic layer 100, and an upper electrode 12. The organic layer 100 contains a hole transporting layer 4, an electron blocking layer 5, a light emitting layer (blue light emitting layer 6, green light emitting layer 7, and red light emitting layer 8), a hole blocking layer 9, an electron transporting layer 10, a buffer layer 11, etc. Respective layers forming the organic layer 100 may be in contact to each other or another layer may be interposed between each of them. The light extraction substrate 18 has a first light extraction layer 15, a second substrate 16, and a second light extraction layer 17. The organic light-emitting element substrate 13 and the light extraction substrate 18 are closely bonded by way of a high refractive index resin layer 14. A driving device or the like are provided to the organic light-emitting device in FIG. 1 to form a light source device. One of the electrodes for the lower electrode 2 or the upper electrode 12 has a reflection function. In this embodiment, the upper electrode 12 serves as a transparent electrode for transmitting emission light and the lower electrode 2 serves as a reflection electrode.

The organic light-emitting device is expected, for example, as a flat type illumination device and an illumination device for liquid crystal display device. When a voltage is applied between the lower electrode 2 and the upper electrode 12, holes and electrons injected from the lower electrode 2 and the upper electrode 12 are re-combined to emit light in the light emitting layer.

<Reflection Electrode>

The reflection electrode includes inorganic materials of metals such as Al film, indium, molybdenum, and nickel, alloys thereof, and polysilicon and amorphous silicon. It also includes a stacked film in which a transparent conductive film such as of a tin oxide, indium oxide, indium-tin oxide (ITO), indium-zinc oxide (IZO), etc is formed over the metal or the alloy described above.

<Hole Transporting Layer>

The hole transporting layer 4 transports holes and injects them into the light emitting layer. Accordingly, the hole transporting layer 4 preferably comprises a hole transporting material of high hole mobility. Further, the hole transporting layer 4 preferably has chemical stability, high ionization potential, small electron affinity and high glass transition point. The hole transporting layer includes preferably, for example, N,N′-bis(3-methylphenyl)-N,N′-diphenyl-[1,1′-biphenyl]-4,4′ diamine (TPD), 4,4′-bis[N-(1-naphthyl)-N-phenylamino]biphenyl (α-NPD), 4,4′4″-tri(N-carbazolyl)triphenylamine (TCTA), 1,3,5-tris[N-(4-diphenylaminophenyl)phenylamino]-benzene (p-DPA-TDAB), 4,4′,4″-tris(N-carbazole)triphenylamine (TCTA), 1,3,5-tris[N,N-bis(2-methylphenyl)-amino]-benzene (o-MTDAB), 1,3,5-tris(N,N-bis(3-methylphenyl)-amino]-benzene (m-MTDAB), 1,3,5-tris[N,N-bis(4-methylphenyl)-amino]-benzene (p-MTDAB), 4,4′,4″-tris[1-naphthyl(phenyl)amino]triphenylamine (1-TNATA),4,4′,4″-tris[2-naphthyl(phenyl)amino]triphenylamine (2-TNATA),4,4′,4″-tris[biphenyl-4-yl-(3-methylphenyl)amino]triphenylamine (p-PMTDATA), 4,4′,4″-tris[9,9-dimethylfluorene-2-yl(phenyl)amino]triphenylamine (TFATA), 4,4′,4″-tris(N-carbazoyl)triphenylamine (TCTA), 1,3,5-tris-[N-(4-diphenylaminophenyl)phenylamino]-benzene (p-DPA-TDAB), 1,3,5-tris[4-[methylphenyl(phenyl)amino]phenyl]-benzene (MTDAPB), N,N′-di(biphenyl-4-yl)-N,N′-diphenyl[1,1′-biphenyl]-4,4′-diamine (p-BPD), N,N′-bis(9,9-dimethylfluorene-2-yl)-N,N′-diphenylfluorene-2,7-diamine (PFFA), N,N,N′,N′-tetrakis(9,9-dimethylfluorene-2-yl)-[1,1-biphenyl]4,4′-diamine (FFD), (NDA)PP, 4-4′-bis[N,N′-(3-tolyl)amino]-3-3′-dimethylbiphenyl (HMTPD), etc., and they may be used each alone or two or more of them may be used together.

Optionally, a hole injection layer may be disposed between the lower electrode 2 and the hole transporting layer 4. For lowering an injection barrier between the lower electrode 2 and the hole transporting layer 4, the hole injection layer is preferably formed of a material having an appropriate ionization potential. Further, the hole injection layer preferably serves to fill the unevenness on the surface of an underlying layer. The hole injection layer includes, for example, copper phthalocyanine, starburst amine compound, polyanyline, polythiophene, vanadium oxide, molybdenum oxide, ruthenium oxide, and aluminum oxide.

Further, an oxidant may be incorporated in the hole transporting material. This can lower the barrier between the lower electrode 2 and the hole transporting layer 4 or can improve electroconductivity. As the oxidant, Lewis acid compounds such as ferric (II) chloride, ammonium chloride, gallium chloride, indium chloride, and antimony pentachloride, electron accepting compounds such as trinitrofluorene, vanadium oxide, molybdenum oxide, ruthenium oxide, aluminum oxide, and tungsten oxide mentioned as the hole injecting material, etc. can be used and they may be used each alone or two or more of them may be used together.

<Electron Blocking Layer>

The electron blocking layer 5 serves to confine electrons in the light emitting layer. For this purpose, the layer preferably has less electron affinity compared with the organic material forming the light emitting layer. Further, it serves to transport holes injected from the hole transporting layer 4 and injecting them into the light emitting layer. In view of the above, it is preferred that the electron blocking layer 5 comprises a hole transporting material having high hole mobility and small electron affinity. The material includes, for example, di-[4-(N,N-dioctyl-amino)-phenyl]cyclohexane (TAPC), 2,2′,7,7′-tetrakis(N,N-diphenylamino)-9,9-spirobifluorene (sp-TAD), tris(phenylpirazole)iridium (Ir(ppz)₃), and they may be used each alone or two or more of them may be used together.

<Light Emitting Layer>

The blue light emitting layer 6, the green light emitting layer 7, and the red light emitting layer 8 include a case where the host material composed of the light emitting layer emits light and a case where a dopant material added in a trace amount to the host emits light. It is defined as blue light emission when the center wavelength of the emission spectra is within a range from 430 to 490 nm, as green emission when it is in a range from 500 to 550 nm, and as red light emission when it is in a range from 580 to 650 nm.

The host material includes, for example, distyryl arylene derivatives (DPVBi), syrol derivatives having a benzene ring in the skeleton (2PSP), oxodiazole derivatives (EM2) having a triphenyl amine structure on both ends, perinone derivatives having a phenanthrene group (P1), oligothiophene derivatives having a triphenylamine structure on both ends (BMA-3T), perylene derivatives (tBu-PTC), tris(8-quinolinole)aluminum, polyparaphenylene derivatives, polythiophene vinylene derivatives, polyparaphenylene derivatives, polysilane derivatives, polyacetylene derivatives, carbazole derivatives, fluorene derivatives or arylsilane derivatives and they may be used each alone or two or more of them may be used together.

The dopant material contained in the light emitting layer includes, for example, quinacridone, coumarine 6, Nile red, rubrene, 4-(dicyanomethylene)-2-methyl-6-(para-dimethylaminostylyl)-4H-piran (DCM), dicarbazole derivatives, porphyrin platinum complexes (PtOEP), and iridium complexes (Ir(ppy)₃), and they may be used each alone or two or more of them may be used together.

<Hole Blocking Layer>

The hole blocking layer 9 serves to confine holes in the light emitting layer. Accordingly, it is preferred that the ionization potential is larger compared with the organic material forming the light emitting layer. Further, it serves to transport electrons injected from the electron transporting layer 10 to be described later and inject them into the light emitting layer. In view of the above, the hole blocking layer 9 preferably comprises an electron transporting material having high electron mobility and high ionization potential. The material includes, for example, Bathocuproin (BCP), bis(2-methyl-8-quinolinate)-4-(phenylphenolate)aluminum (BAlq), and tris(2,4,6-trimethyl-3-(pyridine-3-yl)phenyl)borane (3TPYMB) and they may be used each alone or two or more of may be used together.

<Electron Transporting Layer>

The electron transporting layer 10 transports electrons and injects them into the light emitting layer. Accordingly, the electron transporting layer 10 preferably comprises an electron transporting material of high electron mobility. The electron transporting layer 10 preferably includes, for example, tris(8-quinolinol)aluminum, oxadiazole derivatives, syrol derivatives, zinc benzothiazole complexes, etc. or the organic materials used for the hole blocking layer described above and they may be used each alone or two or more of them can be used together.

The electron transporting layer 10 preferably a reducing agent in the electron transporting material described above to lower the barrier between the buffer layer 11 and the electron transporting layer 10, or improve the electroconductivity of the electron transporting layer 10. The reducing agent includes, for example, alkali metals, alkaline earth metals, alkali metal oxides, alkaline earth oxides, rare earth oxides, alkali metal halides, alkaline earth halides, rare earth halides, complexes formed of alkali metals and aromatic compounds, etc. Particularly preferred alkali metals are Cs, Li, Na, and K. The materials are not particularly restricted and the materials may be used each alone or two or more them can be used together.

Further, an electron injection layer may be interposed between the upper electrode 12 or the buffer layer 11 and the electron transporting layer 10 to improve the electron injection efficiency. The electron injection layer includes, preferably, for example, lithium fluoride, magnesium fluoride, calcium fluoride, strontium fluoride, barium fluoride, magnesium oxide, and aluminum oxide. The layer is not restricted to such materials and the materials can be used each alone or two or more of them can be used together.

<Buffer Layer>

The buffer layer 11 is a layer formed between the organic film as an underlying layer and a transparent layer when the transparent electrode is formed so as not to damage the organic film as the underlying layer. The buffer layer 11 is formed of an inorganic material. As the material for the buffer layer 11 of a top cathode structure illustrated in FIG. 1, a metal material such as magnesium, silver, etc. are preferred. The materials may be used each alone or in the form of an alloy using two or more of them together. Further, as the material for the buffer layer 11 of a top anode structure using the upper electrode 12 and the anode includes, for example, vanadium oxide, molybdenum oxide, and tungsten oxide.

<Transparent Electrode>

For the transparent electrode material, any material having transparency and high work function can be used. Specifically, the material includes conductive oxides such as ITO and IZO. The electrode can be patterned generally on a substrate such as made of glass by using, for example, photolithography.

<High Refractive Index Resin Layer>

The high refractive index resin layer 14 has a function of closely bonding the organic light-emitting element substrate 13 formed from the lower electrode 2 to the upper electrode 12 and the light extraction substrate 18 to be described later. Light emitted in the blue light emitting layer 6, the green light emitting layer 7, and the red light emitting layer 8 is incident by way of the high refractive index resin layer 14 on the light extraction substrate 18. The refractive index of the blue light emitting layer 6, the green light emitting layer 7, and the red light emitting layer 8 is about 1.8. Accordingly, it is preferred to make the refractive index of the high refractive index resin layer 14 higher thereby decreasing the total reflection light at the boundary between the upper electrode 12 and the high refractive index resin layer 14 and increasing the amount of incident light on the light extraction substrate 18.

The refractive index of the high refractive index resin layer is preferably 1.6 or more. Further, since the high refractive index resin layer 14 has transparency, the thickness of the high refractive index resin layer 14 is preferably 5 μm or more and 200 μm or less. This is because an undesired effect is imposed on the design of optical interference of the organic light-emitting element if the thickness of the high refractive index resin layer 14 is less than 5 μm, and also because the layer tends to be fractured upon pulling if the thickness of the high refractive index resin layer 14 is great than 200 μm.

The high refractive index layer 14 has a configuration in which an inorganic resin is dispersed in a binder. The constituent materials are to be described below.

<Binder>

For the binder as the constituent element of the high refractive index resin layer 14, resins having adhesion and tackiness such as acrylic type or silicone type resins can be utilized. Specifically, the binder includes resins formed by polymerization of monomers such as a 2-ethylhexyl acrylate, butyl acrylate, 2-methoxyethyl acrylate, vinyl acetate, acrylonitrile, styrene, methyl methacrylate, ethyl acrylate, and methyl acrylate, solely or by copolymerization of several kinds of them, addition reaction type silicone, peroxide silicone, epoxy, etc. They may be used alone or two or more of them may be used in admixture or by copolymerization. Further, the binder preferably has adhesion.

Further, when the content of the inorganic particles in the binder is large, that is, the volumic percentage of the inorganic particles is 30 vol % of more, the inorganic particles exposed to the surface contribute effectively to the adhesion of the high refractive index resin layer. Accordingly, when the volumic content of the inorganic particles is high, various kinds of resins such as non-adhesive rubber type or hydrocarbon type, and silicone type resins can be used for the binder. Specifically, the binder includes isoprene, styrene butadiene, polyisobutylene, styrene butadiene styrene, styrene isoprene styrene, styrene ethylene butylene styrene, styrene ethylene propylene styrene, polybutadiene, addition reaction type silicone, peroxide silicone, polypropylene, and polyethylene. They may be used each alone or two or more of them may be used in admixture or by copolymerization. The volumic ratio of the inorganic particles is preferably 5 vol % or more and 50 vol % or less. The volumic ratio of the inorganic particles means a volumic percent of the inorganic particles based on the total amount of the inorganic particles and the binder.

[Inorganic Particles]

As the inorganic particles which are the constituent element of the high refractive index resin layer 14, any particle having less absorption to the wavelength of light to be used and higher refractive index than the binder may be used. Particularly, when the wavelength of the light to be used is that of visible light (380 nm or more and 780 nm or less), metal oxides of high refractive index (refractive index of 1.6 or more and 2.6 or less) and having high transparency to the visible light region such as titanium oxide, zirconium oxide, tin oxide, and barium titanate are preferred as the inorganic particles. Further, by decreasing the size of the inorganic particles to less than the wavelength of light, scattering in the high refractive index resin layer 14 can be suppressed. Assuming the use of visible light, scattering caused by the difference of the refractive index between the inorganic particle and the binder can be decreased by using inorganic particles having an average particle diameter of 100 nm or less, preferably, 50 nm or less. On the other hand, if the particle diameter is excessively fine, since the crystal structure of the metal oxide becomes amorphous, the refractive index of the metal oxide is lower than the refractive index of a bulk to lower the effect of increasing the refractive index. Accordingly, the average particle diameter of the inorganic particles is preferably 5 nm or more. The average particle diameter referred to herein is that determined by a dynamic scattering method. The refractive index of each of the high refractive index resin layer 14 and the binder is measured by a prism coupler method. “Adhesion” is determined by bonding two sheets of glass substrates by way of an object to measure the adhesion, pulling the glass substrates perpendicular to the surface of bonding and decided based on the force per unit area when glass is detached.

If the amount of the inorganic particles mixed in the high refractive index resin layer 14 increases, adhesion is lowered since the ratio of the binder decreases. Accordingly, it is preferred to have a polymer covering the inorganic particles entirely or partially.

[Polymer]

The polymer covering the inorganic particles entirely or partially has a bonding site X and a substituent Y and chemically bonded to the inorganic particle by way of the bonding site X as the side chain of the polymer. For example, the polymer is prepared as described below.

At first, a silane coupling agent having a substituent X′ as a portion of the bonding site X and an inorganic particle are bonded to deposit the silane coupling agent to the surface of the inorganic particle. In this case, the silane coupling agent is deposited to the surface of the inorganic particle such that the substituent X′ does is directly reacted with the inorganic particle but present on the outermost surface of the silane coupling agent (on the side not in contact with the inorganic particle) covering the inorganic particle. Then, the polymer having the substituent Y and the substituent X′ are chemically bonded to form the bonding site X. When the number of the substituents Y is more than the number of the substituents X′, the substituents Y remain after forming the bonding site X. The inorganic particles may be dispersed in a dispersing solvent such as ethylene glycol to bond the silane coupling agent and the inorganic particle. The dispersing solvent includes, for example, glycerine and water. The dispersing solvent dissolves the silane coupling agent tending to fit the silane coupling agent tends to fit the surface of the inorganic particle. When the inorganic particles are dispersed in the dispersing solvent such as ethylene glycol, a micro amount of dispersing medium sometimes remains.

As the silane coupling agent, there may be considered N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-isocyanate propyltriethoxysilane, etc.

For example, when the substituent X′ is one of amino group, isocyanate group, hydroxyl group, or carboxyl group, and the substituent Y is a hydroxyl group or a carboxyl group, the bonding site X is one of amide bond (NHCO), ester bond (OCO), ether bond (O), and urethane bond (NHCOO). One or two of the bonding sites X may be used for the polymer.

The substituent Y that can bond the substituent X′ to form the bonding site X and develop adhesion is preferred, and hydrophilic hydroxyl group, carboxyl group, amino group, and sulfo group are suitable. “Developing adhesion” referred to herein means that when two sheets of glass substrates are bonded by way of a polymer and they are pulled perpendicular to the bonding surface, a force upon detachment of glass is 0.005 g weight N/mm² or more per unit area. One or two or more of the substituents Y described above may be used for the polymer.

The number average molecular weight of the polymer is preferably 200 or more and 50,000 or less and, more preferably, 2,000 or more and 30,000 or less. If the number average molecular weight of the polymer is excessively small, since the polymer cannot sufficiently cover the surface of the inorganic particle, dispersibility in the binder is lowered. On the other hand, if the number average molecular weight of the polymer is excessively large, since the volume of the polymer increases compared with that of the inorganic particle, the refractive index as the bonded product of the inorganic particle and the polymer (adhesive particle) is lowered. The number average molecular weight is measured by gel permeation chromatography. The polymer includes, for example, polyacrylic acid, polyvinyl alcohol, polyaspartic acid, polyglutamic acid, alginic acid, polyvinyl sulfonic acid, polystyrene sulfonic acid, and amylose. One or two or more of the polymers described above may be used as the polymer.

Further, since the polymer is bonded with an inorganic particle as described above, a polymer of a predetermined molecular weight can be attached to the inorganic particle and the manufacturing process is stabilized more compared with a process of converting monomers into a polymer by polymerizing reaction.

<Light Extraction Substrate>

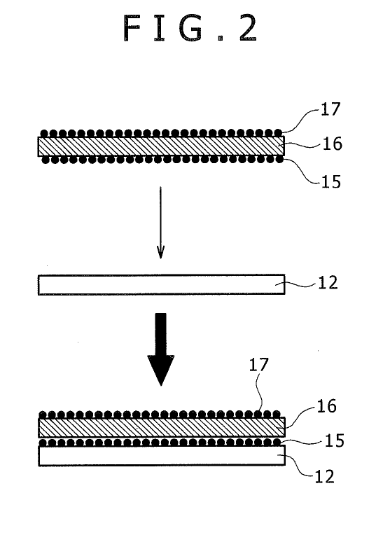

FIG. 2 is a view for preparing a light extraction substrate according to the first embodiment of the invention. A light extraction substrate 18 having a first light extraction layer 15 and a second light extraction layer 17 is closely bonded to the upper electrode 12 of the organic light-emitting element substrate 13 by using the high refractive index resin layer 14. The first light extraction layer 15 is formed to the surface of the second substrate 16 on the side where the upper electrode 12 is present and the second light extraction layer 17 is formed to the surface of the second substrate 16 on the side where the upper electrode 12 is not present.

The refractive index of the organic layer 100 is within a range of about 1.5 or more and 1.9 or less, the refractive index of the transparent electrode used for the upper electrode 12 is about 2.0, and the refractive index of the glass substrate as a typical example of the second substrate 16 is about 1.5. In a configuration where the first light extraction layer 15 and the second light extraction layer 17 are not present, light emitted isotropically in the light emitting layer causes total reflection at the boundary between the high refractive index resin layer 14 and the second substrate 16 and at the boundary between the second substrate 16 and the air layer on the side of a wider angle till light is emitted to an air layer. Accordingly, light confined in the organic layer 100 and light confined in the second substrate 16 are present and the light extraction efficiency of light extracted to the air layer is about 20%. The light extraction efficiency is defined as a value of an external quantum efficiency divided by an internal quantum efficiency. The external quantum efficiency is defined by the number of photons extracted to the air layer relative to the number of electrons or holes injected into the organic layer 100. Further, the internal quantum efficiency is defined as a light emission efficiency inside the organic layer 100.

The refractive index of the binder contained in the first light extraction layer 15 is preferably more than the refractive index of the second substrate 16. Specifically, the refractive index of the binder contained in the first light extraction layer 15 is preferably 1.5 or more and 1.8 or less. It is preferred that the refractive index of the binder contained in the first light extraction layer 15 is 1.7 or more and 1.8 or less in order to increase the amount of light incident on the first light extraction layer 15. The refractive index of the binder contained in the second light extraction layer 17 is preferably more than the refractive index of the second substrate 16. Specifically, the refractive index of the binder contained in the second light extraction layer 17 is preferably 1.5 or more and 1.8 or less. The refractive index in the invention is determined by using an ellipsometric method, a spectral reflection-transmittance measuring method. When the refractive index of fine particles contained in the light extraction layer is sufficiently high, the refractive index of the binder contained in the light extraction layer may be 1.5 or less.

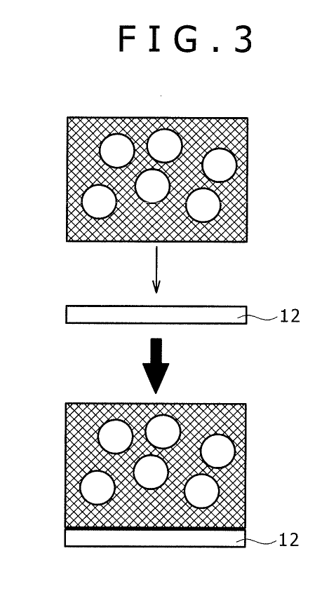

FIG. 3 is a view for preparing a light extraction layer according to the first embodiment of the invention. First, for increasing the dispersibility of particles to a solvent and suppressing aggregation of the particles to each other after coating, the surface of the particles is chemically modified by a silane coupling agent, or a dispersing agent is added to the particles. The particles are dispersed together with a binder material into an organic solvent. Thus, a coating material for forming the first light extraction layer 15 or the second light extraction layer 17 is prepared. As illustrated in FIG. 3, the coating material is applied to the second substrate 16 and the binder material is cured to form a light extraction layer. The material used for the method is to be described below.

(A) Type of Particle

It is necessary that the refractive index of particles forming the light extraction layer is higher than that of the binder material. Specifically, those having a refractive index of 2.0 or more are selected. Further, in the use for illumination, those of white or pale color in a visible region are preferred so that emitted light is not colored. Specifically, they include, for example, titanium oxide (refractive index: 2.5 to 2.7), zirconium oxide (refractive index: 2.4), barium titanate (refractive index: 2.4), strontium titanate (refractive index: 2.37), and bismuth oxide (refractive index: 2.45). The materials may be used each alone or two or more of them may be used together. When desired emission color is chromatic as in traffic lamps (green, yellow, red) or warning lamp (red), particles of a color similar to the chromatic color can be used. Blue particles such as of copper oxide (refractive index: 2.71) can be used for blue emission, red particles such as of ferric oxide (refractive index: 3.01) can be used for red emission, and cadmium oxide (refractive index: 2.49) can be used for yellow emission.

Inorganic oxides with stable properties are suitable for the particles. Further, they are suitable in a case where the binder material is a silica sol since the binding is high.

(B) Size of Particle

Light incident at a wider angle than the total reflection angle on the boundary between the high refractive index resin layer 14 and the first light extraction layer 15 is localized as evanescent waves on the boundary. The particle of the first light extraction layer 15 preferably has a particle diameter that scatters the evanescent waves at an angle larger than the critical angle. Specifically, the average particle diameter of the particle is preferably 0.05 μm or more and 2 μm or less. Further, the size of 0.1 μm or more and 1 μm or less which is identical with the wavelength is more preferred.

Light incident from the second substrate 16 to the second light extraction layer 17 is scattered by fine particles of the second light extraction layer 17 and extracted to the air layer. The average particle diameter of the particles is preferably 1 μm or more and 10 μm or less. Further, the particle diameter is more preferably 1 μm or more and 5 μm or less. The average particle diameter referred to herein the particle diameter determined by the dynamic scattering method.

(C) Specific Gravity of Particle

A particle of high refractive index generally has a large specific gravity. For example, the specific gravity is as large as 6.1 for zirconium oxide, 4.1 or more and 4.2 or less for titanium oxide and 6.1 for barium titanate. Accordingly, dispersibility in the solvent is improved by chemically modifying the surface of the particle with a silane coupling agent. However, since a particle of a particle diameter of about 1 μm or more has a larger surface area relative to the volume, surface chemical modification may be saved sometimes.

(D) Chemical Modification of the Particle Surface

First, a silane coupling agent is added to the organic solvent, to which particles are added and stirred for several hours. After evaporating the solvent by an evaporator, particles are heated at 120° C. for 30 minutes. Thus, the silane coupling agent is bonded by way of a silicon-oxygen bond to the surface of the particle.

If the addition amount of the silane coupling agent to be used is excessive, particles tend to be aggregated after coating the substrate. Then, aggregation of the particles can be suppressed by previously measuring the surface area of the particle by the BET method or the like and using the silane coupling agent in a minimum amount necessary to cover the area.

The silane coupling agent includes those having two or three alkoxy silane groups or those having two or three chloro groups bonded to a silicon atom. Other substituents of silicon than the alkoxy silane group and the chloro group having the following structures are suitable for the dispersion of the particles.

[Compound Group A]

—(CH₂)₃NHCOCH₃—, —(CH₂)₃NHCOCH₂CH₃—, —(CH₂)₃NHCOC₃H₇—, —(CH₂)₃NHCOC₄H₉—, —(CH₂)₃NHCOC₅H₁₁—, —(CH₂)₃NHCOC₆H₁—, —(CH₂)₃NHCOC₇H₁₅—, —(CH₂)₃NHCOC₈H₁₅—.

They are prepared by previously bonding a silane coupling agent having a —(CH₂)₃NH₂ group to the surface of the particle and then reacting a corresponding carboxylic acid to the amino group.

[Compound Group B]

—(CH₂)₃NHCO₂CH₃—, —(CH₂)₃NHCO₂CH₂CH₃—, —(CH₂)₃NHCO₂C₃H₇——(CH₂)₃NHCO₂C₄H₉—, —(CH₂)₃NHCO₂C₅H₁₁—, —(CH₂)₃NHCO₂C₆H₁₃—, —(CH₂)₃NHCO₂C₇H₁₅—, —(CH₂)₃NHCO₂C₈H₁₅—.

They are prepared by previously bonding a silane coupling agent having a —(CH₂)₃NCO group to the surface of the particle and then reacting a corresponding alcohol to the isocyanate group.

In addition, silane coupling agents having isocyanate group, vinyl group, 3-glycidoxypropyl group, 3-chloropropyl group, etc. are suitable to the dispersion of the particles.

Hydrocarbon type substituents, for example, —C₆H₁₃—, —C₈H₁₅—, —C₁₀H₂₁— or aromatic ring substituent, for example, —C₆H₅—, —C₁₀H₇—, etc. can improve the dispersibility to the solvent. However, the substituents described above show no preferred dispersibility and tend to aggregate particles when they are formed as a film. When the silane coupling agent having a bonding site containing a hetero atom such as an amide bond in the substituent is used, the dispersibility tends to be improved when they are formed as the film.

(E) Binder Material

Since the particles are inorganic material, an epoxy resin having high close bondability with the inorganic material is suitable as the binder material. Other organic materials than those described above, acrylic resin, polycarbonate resin, cycloolefinic resin, etc. have high transparency and are suitable.

Light emitted in the light emitting layer causes optical interference through the following plurality of optical channels. A first optical channel in which light is emitted from the organic light-emitting element to the air layer includes: light emitting layer→upper electrode 12→first light extraction layer 15→second substrate 16→second light extraction layer 17→air layer, and the second optical channel includes: light emitting channel→reflection at the lower electrode 2→upper electrode 12→air layer. Optical interference occurs by the light through the optical channels and light further put to multiple reflection in the optical channel described above. Accordingly, it is necessary that the layers constituting the organic light-emitting element to satisfy the optimal interference condition.

In the prior art, it is defined that the total optical length of the organic light-emitting element comprising the organic layer and the transparent electrode is a multiple integer of one-half of the center emission wavelength, or that a value of the total optical length plus one-quarter of the center emission wavelength is an integer multiple of one-half of the center emission wavelength. The optical length is defined herein as a value of a product of the refractive index and the film thickness of a material constituting the organic layer or the transparent electrode.

At first, the emission point of the light emitting layer is defined. The emission point is a position where recombination occurs most frequently between holes and electrons. The emission point is situated at the center of the light emitting layer at a value for the ratio of the hole mobility and the electron mobility in the light emitting layer of 0.2 to 5. The emission point is situated at a boundary between the light emitting layer and an adjacent organic layer situated on the side of the cathode at the mobility ratio of less than 0.2. Further, the emission point is situated at the boundary between the light emitting layer and an adjacent organic layer situated on the side of the anode at the mobility ratio of more than 5. The optical wavelength between the emission point and the lower electrode 2 is defined as L₁.

In the light extraction layer using the first light extraction layer 15 and the second extraction layer 17 used in the invention, the optical length L₁ preferably satisfies the condition of (formula 1). This is the optical condition of maximizing the amount of light in a thick film mode in a case where the first light extraction layer is not present as will be described later. The following (formula 1′) is an existent interference condition.

(2m−155/180)λ₀/4/cos 35°≦L₁≦(2m−155/180)λ₀/4/cos 50° (Formula 1)

(λ₀ is a center emission wavelength of the light emitting layer and m is an integer of 1 or greater).

λ₀ is a center wavelength where the emission spectrum is at the maximum.

L₁=(2m−155/180)λ₀/4 (Formula 1′)

(λ₀ is a center emission wavelength of the light-emitting layer and m is an integer of 1 or greater).

The contents of the invention are to be described more specifically with reference to specific embodiments.

### First Embodiment

An organic light-emitting device according to a first embodiment is to be described. FIG. 1 illustrates an organic light-emitting device according to the first embodiment.

A lower electrode 2 comprising an Al film of 150 nm thickness and an ITO electrode 3 comprising an ITO film of 30 nm thickness were formed over a first substrate 1.

Then, a vapor deposition film of 4,4-bis[N-(1-naphthyl)-N-phenylamino]biphenyl (hereinafter referred to as α-NPD) of 59 nm thickness was formed over the ITO electrode 3 by a vacuum vapor deposition method. The vapor deposition film serves as a hole transporting layer 4.

Then, a TAPC film of 30 nm thickness was formed over the hole transporting layer 4 by a vacuum vapor deposition method. The TAPC film serves as an electron blocking layer 5.

Then, a co-vapor deposition film of N,N′-dicarbazolyl-3,5-benzene (mCP) and bis-[2-(4′,6′-difluorophenyl)pyridinate-N,C^{2′}]iridium (III) picolinate (FIrpic) of 40 nm thickness was formed over the electron blocking layer 5. The vapor deposition rates of CBP, FIrpic were 0.2 nm/sec and 0.014 nm/sec respectively. The co-vapor deposition film serves as a blue light emitting layer 6. The emission spectrum of the emission light from the blue emitting light 6 has a center wavelength of 450 nm.

Then, a film formed by co-vapor deposition of CBP and iridium complex (hereinafter referred to as Ir(ppy)₃) of 30 nm thickness was formed over the blue light emitting layer 6 by a vacuum vapor deposition method. Vapor deposition rates of CBP and Ir(ppy)₃ were 0.20 nm/sec and 0.02 nm/sec, respectively. Ir(ppy)₃ serves as a dopant that determines the emission color. the co-vapor deposition film of CBP and Ir(ppy)₃ serves as a green light emitting layer 7 that emits a green light at a center wavelength of 520 nm.

Then, a film formed by co-vapor deposition of CBP and bis(2-(2′-benzo[4,5-α]thienyl)pyridinate-N, C^{3′})iridium (acetyl-acetonate) (btp₂)Ir(acac)) of 20 nm thickness was formed over the green light emitting layer 7 by a vacuum vapor deposition method. Vapor deposition rates of CBP, btp₂Ir(acac) were 0.2 nm/sec and 0.014 nm/sec, respectively. The co-vapor deposition film serves as a red light emitting layer 8. The center wavelength of the emission spectrum of the light emitting layer 8 was 610 nm.

Then, a film formed by vapor deposition of Bphen of 10 nm thickness was formed over the red light emitting layer 8 by a vacuum deposition method. The vapor deposition film serves as a hole blocking layer 9.

Then, a film obtained by vapor deposition of tris(8-quinolinol)aluminum (hereinafter referred to as Alq₃) was formed over the hole blocking layer 9 by a vacuum vapor deposition method. The vapor deposition film serves as an electron transporting layer 10.

Then, a film of Mg and Ag mixture was formed as a buffer layer 11 over the electron transporting layer 10. In this step, a film of 10 nm thickness was vapor deposited by setting the vapor deposition rates of Mg and Ag to 0.14 nm/s and 0.01 nm/s respectively by using a co-evaporation method. method.

Then, an IZO film of 50 nm thickness was formed over the buffer layer 11 by a sputtering method. The IZO film serves as an upper electrode 12. The IZO film is an amorphous oxide film. The target satisfying In/(In+Zn)=0.83 was used in this step. The film deposition condition included an atmosphere of Ar:O₂ gas mixture, a vacuum degree of 0.2 Pa and a sputtering power of 2 W/cm². The transmittance of the Mg:Ag/In—Zn—O stacked film was 65%. Thus, an organic light-emitting element substrate 13 is formed.

Then, a first light extraction layer 15 was formed over a glass substrate as a second substrate 16. The binder is an epoxy resin. Particles dispersed in the binder comprised titanium oxide having an average particle diameter of 0.2 μm. The thickness of the first light extraction layer 15 was 5 μm. Then, a second light extraction layer 17 was formed over the surface opposite to the side where the first light extraction layer 15 was formed. The binder was epoxy resin and particles dispersed in the binder comprised barium titanate of 2 μm thickness. The thickness of the second light extraction layer 17 was 10 μm. Thus, a light extraction substrate 18 is formed.

Then, the organic light-emitting element substrate 13 and the light extraction substrate 18 were closely bonded in a sealing chamber kept at a high dew point. A photo curable resin was drawn to the edge portion of the light extraction substrate 18 by using a well-known seal dispenser device (not illustrated). In the sealing chamber, the light extraction substrate 18 and the organic light-emitting element substrate 13 were adhered and press bonded. A high refractive index resin layer 14 having a refractive index of 1.8 was filled between the two substrates so that no air gap is formed therebetween. Then, a well-known light sealing plate was placed on the outer side of the light extraction substrate 18 so that UV-light is not applied to the entire organic light-emitting element and UV-light is applied on the side of the light extraction substrate 18 to cure the photocurable resin. Thus, the organic light-emitting device according to this embodiment was obtained.

The emission point of blue light emitted in the blue light emitting layer 6 is at the boundary between the blue light emitting layer 6 and the green light emitting layer 7. Accordingly, the optical wavelength is: L₁=(20 nm×2.0+50 nm×1.8+10 nm×1.8+20 nm×1.8)=183 nm. Since λ₀=450 nm, the left side is 163 nm and the right side is 208 nm in the (formula 1) and L₁ satisfies the (formula 1).

Then, the emission point of green light emitted in the green light emitting layer 7 is situated at the midway of the green light emitting layer 7. Accordingly, the optical length is: L₁=(20 nm×2.0+50 nm×1.8+10 nm×1.8+20 nm×1.8+10 nm×1.8)=201 nm. Since λ₀=520 nm, the left side is 181 nm and the right side is 230 nm in the (formula 1) and L₁ satisfies the (formula 1).

Finally, the emission point of red light emitted in the red light emitting layer 8 is at the boundary between the green light emitting layer 7 and the red light emitting layer 8. Accordingly, the optical length is: L₁=(20 nm×2.0+50 nm×1.8+10 nm×1.8+20 nm×1.8+20 nm×1.8)=219 nm. Since λ₀=610 nm, the left side is 212 nm and the right side is 270 nm in the (formula 1) and L₁ is satisfies the (formula 1). Accordingly, each of blue, green and red emission satisfied the optical interference condition of the (formula 1). Thus, light incident in the high refractive index resin layer 14 was 92%.

Due to the difference of the refractive index between the second substrate 16 and the high refractive index resin layer 14, light incident in the second substrate 16 was about 70% in a case where the first light extraction layer 15 was not present. However, in the configuration in which the first light extraction layer 15 was provided, evanescent light to be reflected totally was scattered by the fine particles dispersed in the first light extraction layer 15, and 80% light was incident in the second substrate 16. Light incident in the second substrate 16 is scattered by the fine particles dispersed in the second light extraction layer 17 and 56% light was extracted to an air layer. Thus, the light extraction efficiency was improved by 2.4 times compared with an organic light-emitting element in which a light extraction layer was provided to the configuration of the interference condition in the prior art (formula 1′)). Further, since light emitted to the air layer is emitted after being scattered in the light extraction layer, the emission spectrum in each of the emitting direction was substantially equal and the dependence of the emission spectrum on the view angle was suppressed.

### Second Embodiment

Then, an organic light-emitting device according to a second embodiment is to be described. FIG. 1 illustrates an organic light-emitting device according to the second embodiment. The layer configuration and the manufacturing conditions for the organic light-emitting element were identical with those of the first embodiment. The light extraction substrate 18 had a configuration identical with the light extraction substrate 18 of the first embodiment except that the particle diameter of the scattered fine particles scattering in the first light extraction layer 15 and the particle diameter of the scattered fine particles scattering in the second light extraction layer 17 were different. The particle diameter of titanium oxide dispersed in the first light extraction layer 15 was 50 nm. Further, the particle diameter of barium titanate dispersed in the second light extraction layer 17 was 1 μm. Further, the condition and the process for closely bonding the organic light-emitting element substrate 13 and the light extraction substrate 18 were also identical with those of the first embodiment. The organic light-emitting device of this embodiment was obtained as described above.

Each of blue, green, and red light emitted in the blue light emitting layer 6, the green light emitting layer 7, and the red light emitting layer 8 satisfied the optical interference condition of the (formula 1) in the same manner as in the first embodiment. Thus, light incident in the high refractive index resin layer 14 was 92%. In the configuration in which the first light extraction layer 15 was provided, evanescent light to be reflected totally was scattered by the fine particles dispersed in the first light extraction layer 15 and 75% light was incident in the second substrate 16. The penetration depth of evanescent light into the second substrate 16 was about 50 nm. It is considered that the extraction efficiency was lowered compared with that in the first embodiment since the average particle diameter of the fine particles dispersed in the first light extraction layer 15 is 50 nm. The light incident in the second substrate 16 was scattered by the fine particles dispersed in the second light extraction layer 17, and 53% light was extracted to the air layer. Thus, the light extraction efficiency was improved by 2.7 times compared with the organic light-emitting element in which the light extraction layer was provided for the layer configuration under the interference condition of the prior art. Further, in the same manner as in the first embodiment, the emission spectrum was substantially equal in each of the emission directions and the dependence of the emission spectrum on the view angle was suppressed.

### Third Embodiment

Then, an organic light-emitting device according to a third embodiment is to be described. FIG. 1 illustrates an organic light-emitting device according to the third embodiment. The layer configuration and the process were identical with those of the first embodiment except that titanium oxide of 50 nm particle diameter was dispersed in the first light extraction layer 15 and barium titanate of 10 μm particle diameter is dispersed in the second light extraction layer 17. Thus, the organic light-emitting device of this embodiment was obtained.

Each of blue, green and red light emission emitted in the blue light emitting layer 6, the green light emitting layer 7 and the red light emitting layer 8 satisfied the optical interference condition of the (formula 1) in the same manner as in the first embodiment. Thus, light incident in the high refractive index resin layer 14 was 92%. In the configuration in which the first light extraction layer 15 was provided, the evanescent light to be reflected totally was scattered by the fine particle dispersed in the first light extraction layer 15, and 75% light was incident in the second substrate 16. The light incident in the second substrate 16 was scattered by the fine particles dispersed in the second light extraction layer 17 and 56% light was extracted to the air layer. It was considered that backward scattering increased and the ratio of light extracted from the second substrate 16 to the air layer was lowered compared with the first embodiment, since the average particle diameter of the fine particles dispersed in the light extraction layer 17 was increased to 10 μm. Thus, the light extraction efficiency was improved by 2.8 times compared with the organic light-emitting element in which the light extraction layer was provided for the layer configuration under the interference condition of the prior art. Further, emission spectrum was substantially equal in each of the emission directions and the dependence of the emission spectrum on the view angle was suppressed.

### Fourth Embodiment

Then, an organic light-emitting device according to a fourth embodiment is to be described. FIG. 1 illustrates an organic light-emitting device according to the fourth embodiment. The layer configuration and the process were identical with those of the first embodiment except that titanium oxide of 1 μm particle diameter was dispersed in the first light extraction layer 15 and barium titanate of 1 μm particle diameter was dispersed in the second light extraction layer 17. Thus, the organic light-emitting device of this embodiment was obtained.

Each of blue, green and red light emitted in the blue light emitting layer 6, the green light emitting layer 7 and the red light emitting layer 8 satisfied the optical interference condition of the (formula 1) in the same manner as in the first embodiment. Thus, light incident in the high refractive index resin layer 14 was 92%. In the configuration where the first light extraction layer 15 was provided, the evanescent light to be reflected totally was scattered by the fine particles dispersed in the first light extraction layer 15, and 85% light was incident in the second substrate 16. Light incident in the second substrate 16 was scattered by the fine particles dispersed in the second light extraction layer 17 and 60% light was extracted to the air layer. Thus, the light extraction efficiency was improved by 3.0 times compared with the organic light-emitting element in which the light extraction layer was provided to the layer configuration under the interference condition of the prior art. Emission spectrum in each of the emission directions was substantially equal and the dependence of the emission spectrum on the view angle was suppressed.

### Fifth Embodiment

Then, an organic light-emitting device according to a fifth embodiment is to be described. FIG. 1 illustrates an organic light-emitting device according to the fifth embodiment. The layer configuration and the process were identical with those of the first embodiment except that titanium oxide of 50 nm particle diameter was dispersed in the first light extraction layer 15 and barium titanate of 10 μm particle diameter was dispersed in the second light extraction layer 17. Thus, the organic light-emitting device of this embodiment was obtained.

Each of blue, green and red emission emitted in the blue light emitting layer 6, the green light emitting layer 7 and the red light emitting layer 8 satisfied the optical interference condition of the (formula 1) in the same manner as in the first embodiment. Thus, light incident in the high refractive index resin layer 14 was 92%. In the configuration where the first light extraction layer 15 was provided, the evanescent light to be reflected totally was scattered by the fine particles dispersed in the first light extraction layer 15, and 85% light was incident in the second substrate 16. The light incident in the second substrate 16 was scattered by the fine particles dispersed in the second light extraction layer 17 and 56% light was extracted to the air layer. Thus, the light extraction efficiency was improved by 2.8 times compared with the organic light-emitting element in which the light extraction layer was provided to the layer configuration under the interference condition of the prior art. Further, emission spectrum was substantially equal in each of the emission directions and the dependence of the emission spectrum on the view angle was suppressed.

### Comparative Example 1

Then, an organic light-emitting device manufactured as Comparative Example 1 is to be described. FIG. 1 illustrates an organic light-emitting device according to Comparative Example 1. The layer configuration and manufacturing conditions of the organic light-emitting element were identical with those of the first embodiment except for the film thickness of a portion of the organic layer. Specifically, the thickness of the α-NPD film used for the hole transporting layer 4 was 16 nm, the thickness of the TAPC film used for the electron blocking layer 5 was 10 nm, the thickness of the co-vapor deposition film of CBP and FIrpic used for the blue light emitting layer 6 was 9 nm, and the thickness of the co-vapor deposition film of CBP and Ir(ppy)₃ used for the green light emitting layer 7 was 12 nm. The light extraction substrate 18 was prepared as described below. The first light extraction layer 15 was formed over a glass substrate as the second substrate 16. The binder was an epoxy resin. Particles dispersed in the binder comprised aluminum oxide having an average particle diameter of 1.2 μm. The thickness of the first light extraction layer 15 was 5 μm. Then, the second light extraction layer 17 was formed over the surface opposite to the side where the first light extraction layer 15 was formed. The binder was an epoxy resin and particles described in the binder comprised aluminum oxide of 12 μm thickness. Thus, a light extraction substrate 18 was formed. Conditions and process for closely bonding the organic light-emitting element substrate 13 and the light extraction substrate 18 were identical with those of the first embodiment.

Emission points of blue, green, and red light emitted in the blue light emitting layer 6, the green light emitting layer 7, and the red light emitting layer 8 were identical with those of the first embodiment. Accordingly, L₁ for each of blue, green and light emission was 107 nm, 123 nm, and 145 nm respectively. Therefore, L₁ for all of the emission colors satisfied the optical interference condition of the (formula 1′). Since the average refractive index of the first light extraction layer 15 was 1.6, light incident in the first light extraction layer 15 and the second extraction substrate 16 was 45% due to the difference of the refractive index between the first light extraction layer 15 and the high refractive index resin layer 14. It is considered that the efficiency of extraction to the second substrate 16 was lowered since the average particle diameter of the fine particles dispersed in the first light extraction layer 15 was 1.2 μm, and light at an angle smaller than a critical angle to form evanescent wave was scattered. Further, it is considered that since the average refractive index of the first light extraction layer 15 was lowered, the scattering effect at the fine particles was lowered to lower the extraction efficiency. Light incident in the second substrate 16 was propagated in the second light extraction layer 17, scattered by the fine particles dispersed in the second light extraction layer 17 and 23% light was extracted to the air layer. It is considered that since the average particle diameter of the fine particles dispersed in the first light extraction layer 17 was increased as large as 12 μm, backward scattering increased to lower the ratio of the light extracted from the second substrate 16 to the air layer was lowered compared with that in the first embodiment.

### Comparative Example 2

Then, an organic light-emitting device manufactured as Comparative Example 2 is to be described. FIG. 1 illustrates an organic light-emitting device according to Comparative Example 2. The layer configuration and manufacturing conditions of the organic light-emitting device are identical with those of the first embodiment. On the other hand, the light extraction substrate was prepared as described below. The first light extraction layer 15 was formed over a glass substrate as the second substrate 16. The binder was an epoxy resin. Particles dispersed in the binder comprised titanium oxide of 0.2 μm average particle diameter. The thickness of the light extraction layer was 5 μm. Then, the second light extraction layer 17 was formed over the surface opposite to the side where the first light extraction layer 15 was formed. The preparation conditions were identical with those of Comparative Example 1. Thus, the light extraction substrate 18 was formed. Conditions and process for closely bonding the organic light-emitting element substrate 13 and the light extraction substrate 18 were also identical with those of the first embodiment.

Each of blue, green and red light emitted in the blue light emitting layer 6, the green light emitting 7 and the red light emitting layer 8 satisfied the optical interference condition of the (formula 1) in the same manner as in the first embodiment. Thus, light incident in the high refractive index resin layer 14 was 92%. Since, the average refractive index of the first light extraction layer was 1.8 and the particle diameter of the scattered particles was 200 nm, evanescent light reflected by the first light extraction layer 15 was scattered by the fine particle and 80% light was incident in the second substrate 16. Light incident in the second substrate 16 was propagated in the second light extraction layer 17, scattered by the fine particles dispersed in the second light extraction layer 17 and 40% light was extracted to the air layer. Thus, the light extraction efficiency was improved by about 2.0 times compared with the organic light-emitting element in which the light extraction layer was provided in the layer configuration under the interference condition of the prior art.

### Comparative Example 3

Then, an organic light-emitting device manufactured as Comparative Example 3 is to be described. FIG. 1 illustrates an organic light-emitting device according to Comparative Example 3. The layer configuration and manufacturing condition of the organic light-emitting element were identical with those of the first embodiment. On the other hand, the light extraction substrate 18 was prepared as described below. The first light extraction layer 15 was formed over a glass substrate as the second substrate 16. The binder was an epoxy resin. Particles dispersed in the binder comprised titanium oxide of 1.2 μm average particle diameter. The thickness of the light extraction layer was 5 μm. Then, the second light extraction layer 17 was formed over the surface opposite to the side where the first light extraction layer 15 was formed. The conditions were identical with those of Comparative Example 1 except that the particle diameter of aluminum oxide was 2 μm. Thus, the light extraction substrate 18 was formed. Conditions and process of closely bonding the organic light-emitting element substrate 13 and the light extraction substrate 18 were also identical with those of the first embodiment.

Each of blue, green and red emission emitted in the blue light emitting layer 6, the green light emitting 7 and the red light emitting layer 8 satisfied the optical interference condition of the (formula 1) in the same manner as in the first embodiment. Thus, light incident in the high refractive index resin layer 14 was 92%. Since, the average refractive index of the first light extraction layer was 1.8 and the particle diameter of the scattered particles was 200 nm, evanescent light reflected by the first light extraction layer 15 was scattered by the fine particle and 60% light was incident in the second substrate 16. Light incident in the second substrate 16 was propagated in the second light extraction layer 17, scattered by the fine particles dispersed in the second light extraction layer 17 and 43% light was extracted to an air layer. Thus, the light extraction efficiency was improved by about 2.2 times compared with the organic light-emitting element in which the light extraction layer was provided to the layer configuration under the interference condition of the prior art.

### Sixth Embodiment

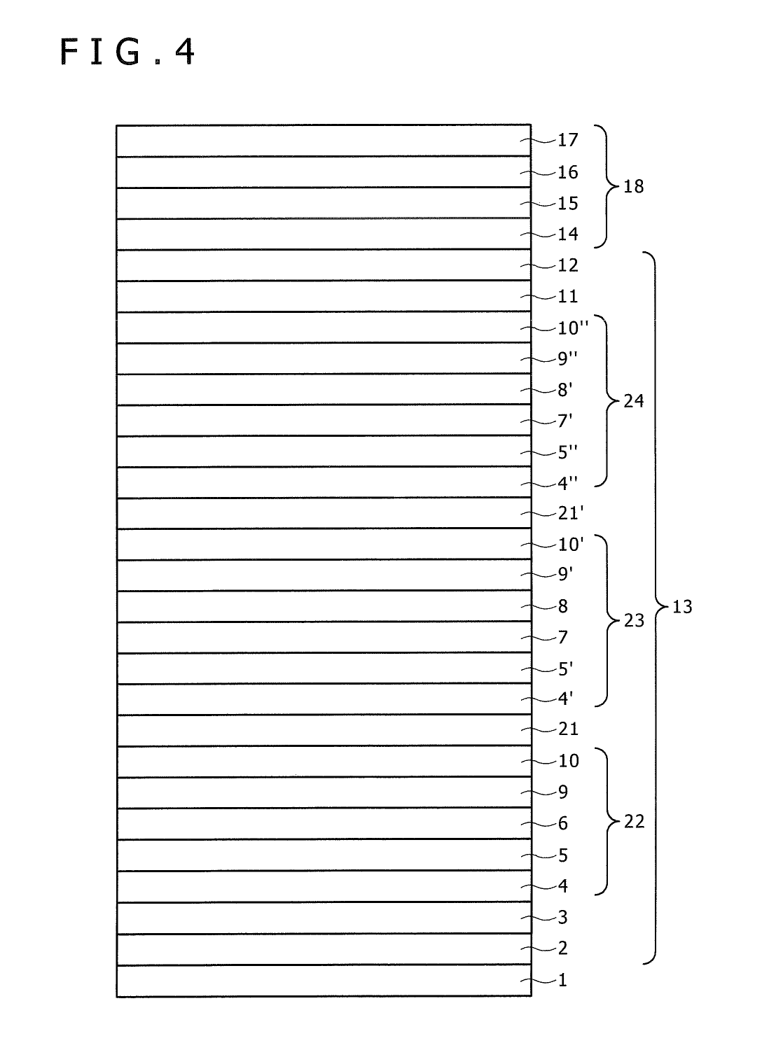

Then, an organic light-emitting device according to a sixth embodiment is to be described. FIG. 4 is a cross sectional view of an organic light-emitting device according to the sixth embodiment. The organic light-emitting device had a substrate 1 as a first substrate and an organic light-emitting element substrate 13 in which an organic light-emitting element was disposed over the substrate 1. The organic light-emitting device had, over a lower electrode 2 as an anode and an ITO electrode 3, a first light emission unit 22 comprising a hole transporting layer 4, an electron blocking layer 5, a blue light emitting layer 6, a hole blocking layer 9, and an electron transporting layer 10, a second light emission unit 23 comprising a hole transporting layer 4′, an electron blocking layer 5′, a green light emitting layer 7, a red light emitting layer 8, a hole blocking layer 9′ an electron transporting layer 10′ and an electron transporting layer 10′, a third light emitting 24 comprising a hole transporting layer 4″, an electron blocking layer 5″, a green light emitting layer 7′, a red light emitting layer 8′, a hole blocking layer 9″, an electron transporting layer 10″, a buffer layer 11, and an upper electrode 12 as a cathode. A charge generation layer 21 was formed between the first light emission unit 22 and the second emitting unit 23. A charge generation layer 21′ was formed between the second light emission unit 23 and the third emitting unit 24. The first light extraction layer 15 and the second light extraction layer 17 were formed on both sides of a glass substrate as the second substrate 16 to form a light extraction substrate 18. The organic light-emitting element substrate 13 and the light extraction substrate 18 were closely bonded by way of a high refractive index resin layer 14. The lower electrode 2 and the ITO electrode 3 were formed over the substrate 1 under the same conditions as those in the first embodiment.

Then, a hole transporting layer 4 comprising an α-NPD vapor deposition film of 60 nm thickness, an electron blocking layer 5 comprising a TAPC film of 10 nm thickness, a blue light emitting layer 6 comprising a co-vapor deposition film of mCP and FIrpic of 40 nm thickness, a hole blocking layer 9 comprising a vapor deposition film of Bphen of 50 nm thickness, and an electron transporting layer 10 comprising a vapor deposition film of Alq₃ of 10 nm thickness were formed over the ITO electrode 3. Manufacturing conditions for each of the vapor deposition films were identical with those of the first embodiment. Thus, the first light emission unit 22 was formed.

Then, a molybdenum oxide (MoO₃) vapor deposition film of 5 nm thickness was formed as a charge generation layer 21 over the electron transporting layer 10 by a vapor deposition method. Further, the hole transporting layer 4′ comprising an α-NPD vapor deposition film of 100 nm thickness, the electron blocking layer 5′ comprising a TAPC film of 20 nm thickness, the green light emitting layer 7 comprising a co-vapor deposition film of CBP and Ir(ppy)₃ of 20 nm thickness, the red light emitting layer 8 comprising co-vapor deposition film of CBP and btp₂Ir(acac) of 20 nm thickness, the hole blocking layer 9′ comprising a vapor deposition film of Bphen of 100 nm thickness, and an electron transporting layer 10′ comprising a vapor deposition film of Alq₂ of 10 nm thickness were formed thereover. Conditions for preparing each of the vapor deposition films were identical with those of the first embodiment. Thus, the second light emission unit layer 23 is formed.

Then, a molybdenum oxide (MoO₃) vapor deposition film of 5 nm thickness was formed as a charge generation layer 21′ over the electron transporting layer 10′ by a vapor deposition method. The hole transporting layer 4″ comprising an α-NPD vapor deposition film of 120 nm thickness, the electron blocking layer 5″ comprising a TAPC film of 40 nm thickness, the green light emitting layer 7′ comprising a co-vapor deposition film of CBP and It(ppy)₃ of 20 nm thickness, the hole blocking layer 9″ comprising a vapor deposition film of Bphen of 10 nm thickness, and the electron transporting layer 10″ comprising a vapor deposition film of Alq₃ of 10 nm thickness were formed. The conditions for preparing each of the vapor deposition films were identical with those in the first embodiment. Thus, the third light emission unit 24 was formed.

Then, over the electron transporting layer 10″, the buffer layer 11 comprising a film of Mg and Ag mixture and an upper electrode 12 comprising an IZO film of 50 nm thickness were formed over the electron transporting layer 10″. The conditions for preparing each of the layers were identical with those in the first embodiment. Thus, an organic light-emitting element substrate 13 was formed.

Then, the second substrate 16, the first light extraction layer 15, and the second light extraction layer 17 were formed. The conditions for preparing each of the layers were identical with those in the first embodiment. Thus, the light extraction substrate 18 was formed.

Then, the organic light-emitting element substrate 13 and the light extraction substrate 18 were closely bonded under the same preparation conditions as those of the first embodiment. Thus, the organic light-emitting device according to this embodiment was obtained.

The emission points of the blue light emitted in the blue light emitting layer 6 is situated at the midway of the blue light emitting layer 6. Accordingly, the optical wavelength L₁=186 nm. Since λ₀=450 nm, the left side is 163 nm and the right side is 208 nm at m=1 in the (formula 1), and L₁ satisfies the (formula 1). Then, emission points of green light and red light emitted in the second light emission unit 23 are situated at the boundary between the green light emitting layer 7 and the red light emitting layer 8. Therefore, since the wavelength L₁ for the green light emission and the red light emission is: L₁=592 nm. Since λ₀=520 nm, the left side is 498 nm and the right side is 635 nm at m=2 in the (formula 1) for the green light emission and L₁ satisfies the (formula 1). Further, the left side is 531 nm and the right side is 677 nm at m=2 in (formula 1) for the red light emission, and L₁ satisfies the (formula 1).

Finally, emission points of green light and red light emitted in the third light emission unit 24 are situated at a boundary between the green light emitting layer 7′ and the red light emitting layer 8′. Therefore, the optical length of the green light emission and led light emission is: L₁=998 nm. Since λ₀=520 nm, the left side is 831 nm and the right side is 1059 nm at m=3 in the (formula 1) for the green light emission, and L₁ satisfies the (formula 1). The left side is 957 nm and the right side is 1219 nm at m=3 in the (formula 1) for the red light emission, and L₁ satisfies the (formula 1). Accordingly, each of the blue, green and red light emission satisfied the optical interference condition of the (formula 1). Thus, 92% light was incident in the high refractive index resin layer 14. Due to the difference of the refraction index between the second substrate 16 and the high refractive index resin layer 14, about 50% light was incident in the second substrate 16 in a case where the first light extraction layer was not present. However, in the configuration in which the first light extraction layer 15 was provided, evanescent light to be reflected totally was scattered by the fine particles dispersed in the first light extraction layer 15 and 80% light was incident in the second substrate 16. Light incident in the second substrate 16 was scattered by the fine particles dispersed in the second light extraction layer 17 and 56% light was extracted to an air layer. Thus, the light extraction efficiency was improved by 2.8 times compared with the organic light-emitting element in which the light extraction layer was provided in the layer configuration under the interference condition of the prior art. Further, since the light extracted to the air layer was scattered in the light extraction layer and emitted, emission spectrum was substantially equal in each of the emitting directions to suppress the dependence of the emission spectrum on the view angle. According to this embodiment, a current necessary for obtaining a predetermined brightness could be decreased.

### Seventh Embodiment

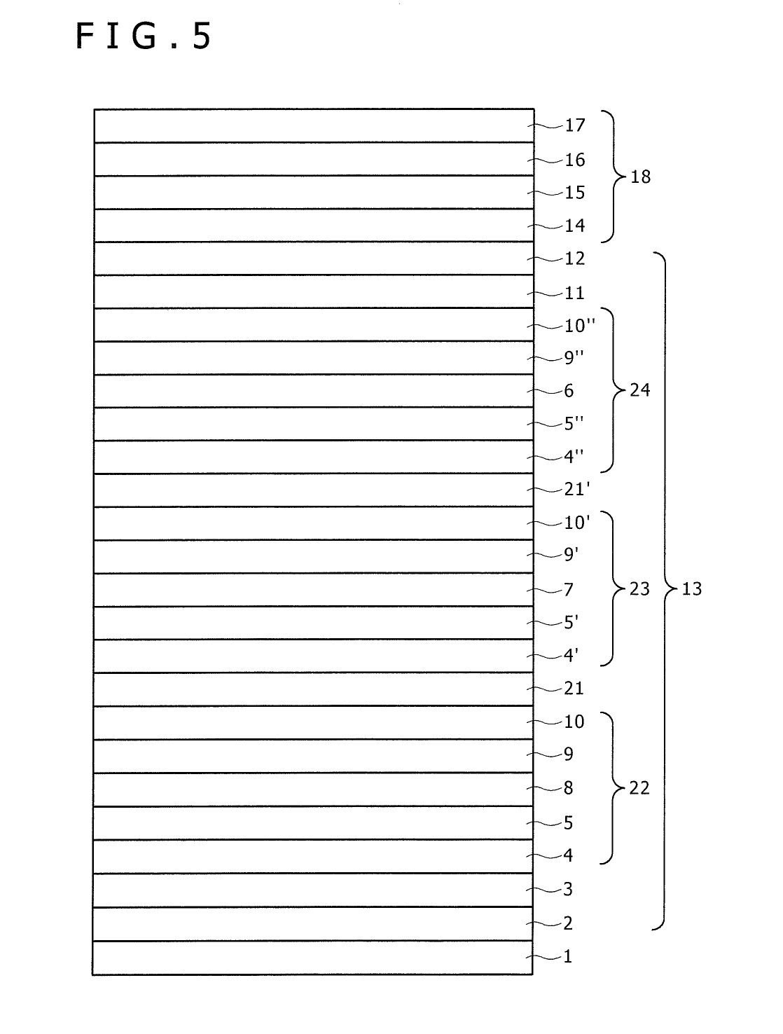

Then, an organic light-emitting device according to a seventh embodiment is to be described. FIG. 5 is a cross sectional view of an organic light-emitting device according to the seventh embodiment. The organic light-emitting device has a substrate 1 as a first substrate and an organic light-emitting element substrate 13 in which an organic light-emitting element is disposed over the substrate 1. The organic light-emitting device has, over a lower electrode 2 as an anode and an ITO electrode 3, a first light emission unit 22 comprising a hole transporting layer 4, an electron blocking layer 5, a red light emitting layer 8, a hole blocking layer 9, and an electron transporting layer 10, a second light emission unit 23 comprising a hole transporting layer 4′, an electron blocking layer 5′ a green light emitting layer 7, a hole blocking layer 9′, and an electron transporting layer 10′, a third light emitting 24 comprising a hole transporting layer 4″, an electron blocking layer 5″, a blue light emitting layer 6, a hole blocking layer 9″ and an electron transporting layer 10″, a buffer layer 11, and an upper electrode 12 as a cathode. A charge generation layer 21 is formed between the first light emission unit 23 and the second light emission unit 24. A charge generation layer 21′ is formed between the second light emission unit 22 and the third light emission unit 23. A first light extraction layer 15 and a second light extraction layer 17 are formed on both sides of a glass substrate as a second substrate 16 to form a light extraction substrate 18. The organic light-emitting element substrate 13 and the light extraction substrate 18 are closely bonded by way of a high refractive index resin layer 14.

The lower electrode 2 and the ITO electrode 3 were formed over the substrate 1 under the same conditions as those in the first embodiment.

Then, a hole transporting layer 4 comprising an α-NPD vapor deposition film of 80 nm thickness, an electron blocking layer 5 comprising a TAPC film of 10 nm thickness, a red light emitting layer 8 comprising a co-vapor deposition layer of CBP and btp₂Ir(acac) of 40 nm thickness, a hole blocking layer 9 comprising a Bphen vapor deposition film of 10 nm thickness, and an electron transporting layer 10 comprising an Alq₃ vapor deposition film of 10 nm thickness were formed over the ITO electrode 3. Conditions for preparing each of the vapor deposition films were identical with those of the first embodiment. Thus, the first light emission unit 22 was formed.

Then, a molybdenum oxide (MoO₃) vapor deposition film of 5 nm thickness was formed as the charge generation layer 21 over the electron transporting layer 10 by a vapor deposition method. Further, the hole transporting layer 4′ comprising an α-NPD vapor deposition film of 85 nm thickness, the electron blocking layer 5′ comprising a TAPC film of 40 nm thickness, the green light emitting layer 7 comprising a co-vapor deposition film of CBP and Ir(ppy)₃ of 40 nm thickness, the hole blocking layer 9′ comprising a Bphen vapor deposition film of 10 nm thickness, and an electron transporting layer 10′ comprising an Alq₃ vapor deposition film of 10 nm thickness were formed thereover. Conditions for preparing each of the vapor deposition films were identical with those of the first embodiment. Thus, the second light emission unit layer 23 was formed.

Then, a molybdenum oxide (MoO₃) vapor deposition film of 5 nm thickness was formed as the charge generation layer 21′ over the electron transporting layer 10′ by a vapor deposition method. The hole transporting layer 4″ comprising an α-NPD vapor deposition film of 75 nm thickness, the electron blocking layer 5″ comprising a TAPC film of 40 nm thickness, the blue light emitting layer 6 comprising a co-vapor deposition film of mCP and FIrpic of 40 nm thickness, the hole blocking layer 9″ comprising a Bphen vapor deposition film of 10 nm thickness, and the electron transporting layer 10″ comprising an Alq₃ vapor deposition film of 10 nm thickness were formed thereover. The conditions for preparing each of the vapor deposition films were identical with those in the first embodiment. Thus, the third light emission unit 24 was formed.

Then, the buffer layer 11 comprising a film of Mg and Ag mixture and an upper electrode 12 comprising an IZO film of 50 nm thickness were formed over the electron transporting layer 10″. The conditions for preparing each of the layers were identical with those in the first embodiment. Thus, an organic light-emitting element substrate 13 was formed.

Then, the second substrate 16, the first light extraction layer 15, and the second light extraction layer 17 were formed. The conditions for preparing each of the layers were identical with those in the first embodiment. Thus, the light extraction substrate 18 was formed.

Then, the organic light-emitting element substrate 13 and the light extraction substrate 18 were closely bonded under the same preparation conditions as those in the first embodiment. Thus, the organic light-emitting device according to this embodiment was obtained.

The emission points of red light emitted in the red light emitting layer 8 is situated at the boundary between the red light emitting layer 6 and the electron blocking layer 5. Accordingly, the optical wavelength is: L₁=220 nm. Since λ₀=610 nm, the left side is 212 nm and the right side is 270 nm at m=1 in the (formula 1), and L₁ satisfies the (formula 1). Then, emission points of green light emitted in the green light emitting layer 7 of the second light emission unit 23 are situated at the boundary between the green light emitting layer 7 and the electron blocking layer 5′. Accordingly, the wavelength of the green light is: L₁=565 nm. Since λ₀=520 nm, the left side is 498 nm and the right side is 635 nm at m=2 in the (formula 1) for the green light emission and L₁ satisfies the (formula 1). Finally, light emission points of blue light emitted in the blue light emitting layer 6 of the third light emission unit 24 are situated at the boundary between the blue light emitting layer 6 and electron blocking layer 5″. Accordingly, the optical length of the blue light emission is: L₁=836 nm. Since λ₀=450 nm, the left side is 706 nm and the right side is 899 nm at m=3 of the (formula 1) for the blue light emission and L₁ satisfies the (formula 1).

Accordingly, each of the blue, green and red light emission satisfied the optical interference condition of the (formula 1). Thus, 92% light was incident in the high refractive index resin layer 14. Due to the difference of refraction index between the second substrate 16 and the high refractive index resin layer 14, about 50% light was incident in the second substrate 16 in a case where the first light extraction layer 15 was not present. However, in the configuration in which the first light extraction layer 15 was provided, evanescent light to be reflected totally is scattered by the fine particles dispersed in the first light extraction layer 15 and 80% light was incident in the second substrate 16. Light incident in the second substrate 16 was scattered by the fine particles dispersed in the second light extraction layer 17 and 56% light was extracted to an air layer. Thus, the light extraction efficiency was improved by 2.8 times compared with the organic light-emitting element in which the light extraction layer was provided in the layer configuration under the interference condition of the prior art. Further, since the light extracted to the air layer was scattered in the light extraction layer and emitted, emission spectrum was substantially equal in each of the emission directions to suppress the dependence of the emission spectrum on the view angle. According to this embodiment, manufacturing process can be simplified since the number of stacking the organic layers is reduced.

### DESCRIPTION OF REFERENCE SIGN

1 substrate
2 lower electrode
3 transparent electrode
4 hole transporting layer
5 electron blocking layer
6 blue light emitting layer
7 green light emitting layer
8 red light emitting layer
9 hole blocking layer
10 electron transporting layer
   11 buffer layer
   12 upper electrode
   13 organic light-emitting element substrate
14 high refractive index resin layer
15 first light extraction layer
   16 second substrate
   17 second light extraction layer
   18 light extraction substrate

1. An organic light-emitting device having an organic light-emitting element substrate and a light extraction substrate in which
the organic light-emitting element substrate has a first substrate, a first electrode, an organic layer, and a second electrode,
the first electrode is formed over the first substrate,
the organic layer is formed over the first electrode,
the second electrode is formed over the organic layer,
the light extraction substrate is formed over the second electrode,
the organic layer contains a light emitting layer,
the light extraction substrate has a first light extraction layer, a second substrate, and a second light extraction layer,
the first light extraction layer is formed over the surface of the second substrate on the side where the second electrode is present,
the second light extraction layer is formed over the surface of the second substrate on the side where the second electrode is not present,
the first light extraction layer contains fine particles and a binder,
the second light extraction layer contains fine particles and a binder,
the average particle diameter of the fine particles contained in the first light extraction layer is 0.05 μm or more and 2 μm or less,
the average particle diameter of the fine particles contained in the second light extraction layer is 1 μm or more and 10 μm or less, and
an optical length L₁ between emission points of the light emitting layer and the first electrode satisfies (formula 1):
(2m−155/180)λ₀/4/cos 35°≦L₁≦(2m−155/180)λ₀/4/cos 50° (Formula 1)
(λ₀ is a center emission wavelength and m is an integer of 1 or more).

2. The organic light-emitting device according to claim 1, wherein
the average particle diameter of the fine particles contained in the first light extraction layer is 0.1 μm or more and 1 μm or less, and
the average particle diameter of the fine particles contained in the second light extraction layer is 1 μm or more and 5 μm or less.

3. The organic light-emitting device according to claim 1, wherein
the organic light-emitting element substrate and the light extraction substrate are closely bonded by way of a high refractive index resin layer,
the refractive index of the high refractive resin layer is 1.6 or more, and
the thickness of the high refractive index layer is 5 μm or more and 200 μm or less.

4. The organic light-emitting device according to claim 1, wherein
the light emitting layer is a blue light emitting layer,
a light emission unit is formed between the organic layer and the second electrode,
the light emission unit includes a red light emitting layer and a green light emitting layer,
a charge generation layer is formed between the light emission unit and the organic layer, and
an optical length L₂ between the emission point of the red light emitting layer and the first electrode, and
an optical length L₃ between the emission point of the green light emitting layer and the first electrode satisfy (formula 2) and (formula 3):
(2m−155/180)λ₁/4/cos 35°≦L₂≦(2m−155/180)λ₁/4/cos 50° (Formula 2)
(λ₁ is a center emission wavelength of the red light emitting layer and m is an integer of 1 or more).
(2m−155/180)λ₂/4/cos 35°≦L₃≦(2m−155/180)λ₂/4/cos 50° (Formula 3)
(λ₂ is a center emission wavelength of the green light emitting layer and m is an integer of 1 or more).

5. The organic light-emitting device according to claim 1, wherein
the light emitting layer is a red light emitting layer,
a first charge generation layer is formed over the organic layer,
a green light emitting layer is formed over the first charge generation layer,
a second charge generation layer is formed over the green light emitting layer,
a blue light emitting layer is formed over the second charge generation layer,
the second electrode is formed over the blue light emitting layer, and
an optical length L₂ between the emission point of the green light emitting layer and the first electrode, and an optical length L₃ between the emission point of the blue light emitting layer and the first electrode satisfy (formula 4) and (formula 5):
(2m−155/180)λ₁/4/cos 35°≦L₂≦(2m−155/180)λ₁/4/cos 50° (Formula 4)
(λ₁ is a center emission wavelength of the green light emitting layer and m is an integer of 1 or more)
(2m−155/180)λ₂/4/cos 35°≦L₃≦(2m−155/180)λ₂/4/cos 50° (Formula 5)
(λ₂ is a center emission wavelength of the blue light emitting layer and m is an integer of 1 or more)

6. The organic light-emitting device according to claim 1, wherein
the fine particles contained in the first light extraction layer comprise one or more of titanium oxide, zirconium oxide, and barium titanate.

7. The organic light-emitting device according to claim 1, wherein
the fine particles contained in the second light extraction layer comprise one or more of titanium oxide, zirconium oxide, and barium titanate.
